(19) United States
(12) Patent Application Publication
(10) Pub. No.: US 2020/0168799 A1
(43) Pub. Date: May 28, 2020

(54) DISPLAY PANEL VAPOR DEPOSITION MASK ASSEMBLY COOLING SYSTEM AND VAPOR DEPOSITION MASK PLATE

(71) Applicant: Wuhan China Star Optoelectronics Semiconductor Display Technology Co., Ltd., Wuhan (CN)

(72) Inventor: Zhao LI, Wuhan (CN)

(73) Assignee: Wuhan China Star Optoelectronics Semiconductor Display Technology Co., Ltd., Wuhan (CN)

(21) Appl. No.: 16/462,241

(22) PCT Filed: Apr. 16, 2019
(86) PCT No.: PCT/CN2019/082830

§ 371 Date: May 20, 2019

(30) Foreign Application Priority Data
Nov. 27, 2018 (CN) 201811429241.2

(51) Int. Cl. H01L 51/00; H01L 51/56

(52) U.S. Cl. CPC H01L 51/0011; H01L 51/56

(57) ABSTRACT

A display panel vapor deposition mask assembly cooling system includes a crucible, a lower cooling pipe disposed around the crucible, and cooling liquid disposed in the lower cooling pipe to suppress heat of the crucible; a vapor deposition mask plate disposed above the crucible, a mask cooling pipe disposed in the vapor deposition mask plate, cooling liquid disposed in mask cooling pipe for cooling the vapor deposition mask plate; a glass substrate disposed above the vapor deposition mask plate; and a magnetic plate disposed above the glass substrate magnetically attracts the vapor deposition mask plate to hold the glass substrate between the vapor deposition mask plate and the magnetic plate, an upper cooling pipe disposed in the magnetic plate and having cooling liquid inside for cooling the magnetic plate. The mask cooling pipe effectively cools the vapor deposition mask plate to prevent temperature of the glass substrate from increasing.

### FIELD OF INVENTION

The present invention relates to a mask plate cooling system, especially to a display panel vapor deposition mask assembly cooling system and a vapor deposition mask plate. The cooling system directly cools the vapor deposition mask plate by circulating cooling liquid, which increases cooling efficiency to the vapor deposition mask plate and a glass substrate and is able to effectively decrease color mixture issues due to heat expansion of the vapor deposition mask plate and the glass substrate during the vapor deposition process. Therefore, a product yield of organic light emitting diode (OLED) display panel products can be greatly improved.

### BACKGROUND OF INVENTION

Organic light emitting diode (OLED) display panel products have advantages of being light in weight, fast response times, wide viewing angles, high contrast, and flexibility, therefore gradually become main display panels, and are mainly applied to fields of cell phones, tablets, and televisions.

Film forming of an OLED material of an OLED display panel is mainly implemented by vapor deposition processes, which by a heating system heats a crucible loaded with the OLED material such that the heated material sublimates and is deposited on a glass substrate through a nozzle.

FIG. 1 is a schematic front view of devices of a conventional vapor deposition process. Devices used by the conventional OLED vapor deposition process include: a crucible 91, a mask plate 94 disposed above the crucible 91, a glass substrate 95 disposed above the mask plate 94, and a magnetic plate 96 disposed above the glass substrate 95. The magnetic plate 96 magnetically attracts the mask plate 94 by a magnetic force such that the glass substrate 95 is clamped and held securely between the magnetic plate 96 and the mask plate 94. A lower cooling pipe 92 is disposed around the crucible 91, and cooling liquid is injected in the lower cooling pipe 92 to suppress heat of the crucible 91. An upper cooling pipe 97 is disposed in the magnetic plate 96, and cooling liquid is injected in the upper cooling pipe 97 to dissipate heat from the magnetic plate 96.

When the above vapor deposition process is implemented, an evaporation source (or called heating source) 911 heats the crucible 91 loaded with the OLED material such that the heated and sublimated OLED material is sprayed from the nozzle on the top of the crucible 91 and is deposited on the glass substrate 95 above. Because sublimating temperatures of most of the OLED material is over 400° C., waste heat of the evaporation source 911 spread onto the mask plate 94 and the glass substrate 95 in form of heat radiation, which causes temperature increase of the mask plate 94 and the glass substrate 95.

Although the cooling system (the lower cooling pipe 92 and the upper cooling pipe 97) is disposed on the crucible 91 and the magnetic plate 96, the cooling capability of the cooling system is limited, a surface temperature of the mask plate 94 and the glass substrate 95 is still higher than room temperature and the temperature difference results in heat expansion and deformation of the mask plate 94 and the glass substrate 95. Heat expansion coefficients of the mask plate 94 and the glass substrate 95 are different and causes different expansion amounts thereof, which result in color mixture during the vapor deposition. Therefore, it is necessary for the OLED vapor deposition process to enhance the cooling system to improve the cooling efficiency of the cooling system to the mask plate 94 and the glass substrate 95 such that the temperature of the mask plate 94 and glass substrate 95 is lowered and the product yield of the color mixture of the OLED display panel is increased.

Therefore, it is necessary to provide a display panel vapor deposition mask assembly cooling system and a vapor deposition mask plate to solve the issue of the prior art.

### SUMMARY OF INVENTION

### Technical Issue

According to the shortage of the cooling system of the conventional organic light emitting diode (Organic Light Emitting Diode, OLED) vapor deposition process, the present invention provides a display panel vapor deposition mask assembly cooling system and a vapor deposition mask plate.

### Technical Solution

A main objective of the present invention is to provide a display panel vapor deposition mask assembly cooling system. The cooling system directly cools the vapor deposition mask plate by circulating cooling liquid, which increases cooling efficiency to the vapor deposition mask plate and the glass substrate and is able to effective decrease an issue of color mixture due to heat expansion of the vapor deposition mask plate and the glass substrate during the vapor deposition process. Therefore, a yield rate of the organic light emitting diode (OLED) display panel products can be drastically improved.

For achieving the above objective of the present invention, the display panel vapor deposition mask assembly cooling system of the present invention is configured to dissipate heat from a vapor deposition mask assembly, and the vapor deposition mask assembly comprises: a vapor deposition mask plate, a glass substrate disposed above the vapor deposition mask plate, and a magnetic plate disposed above the glass substrate; and

the display panel vapor deposition mask assembly cooling system comprising: a mask cooling pipe, disposed in the vapor deposition mask plate, and cooling liquid disposed in the mask cooling pipe and configured to cool the vapor deposition mask plate.

In an embodiment of the present invention, the display panel vapor deposition mask assembly cooling system further comprises: a lower cooling pipe, wherein the cooling liquid is further disposed in the lower cooling pipe.

In an embodiment of the present invention, the display panel vapor deposition mask assembly cooling system further comprises: an upper cooling pipe, disposed in the magnetic plate, wherein the cooling liquid is further disposed in the upper cooling pipe and is configured to cool the magnetic plate.

In an embodiment of the present invention, the mask cooling pipe comprises an inlet end and an outlet end, the cooling liquid in the mask cooling pipe flows along the mask cooling pipe from the inlet end to the outlet end.

In an embodiment of the present invention, the inlet end and the outlet end of the mask cooling pipe are connected to a circulating pump such that the cooling liquid flows cyclically between the mask cooling pipe and the circulating pump.

In an embodiment of the present invention, two connection pipes are disposed on the circulating pump and are connected to the inlet end and the outlet end of the mask cooling pipe respectively, and a distal end of each of the connection pipes is shrunk to form an engaging section engaged with and inserted into the inlet end or the outlet end.

In an embodiment of the present invention, the vapor deposition mask plate comprises a plate member and a frame disposed around a periphery of the plate member; and the mask cooling pipe is disposed in the frame.

In an embodiment of the present invention, the mask cooling pipe is arranged along the frame to form at least one loop surrounding the plate member.

In an embodiment of the present invention, the plate member has a plurality of vapor deposition holes penetrating the plate member.

In an embodiment of the present invention, the frame of the vapor deposition mask plate is rectangular and comprises four sides, the inlet end and the outlet end of the mask cooling pipe are located on one of the sides of the frame.

In an embodiment of the present invention, the lower cooling pipe comprises an inlet end and an outlet end, the cooling liquid in the lower cooling pipe flows along the lower cooling pipe from the inlet end to the outlet end; the inlet end and the outlet end of the lower cooling pipe are connected to a lower pump such that the cooling liquid cyclically flows between the lower cooling pipe and the lower pump.

In an embodiment of the present invention, the upper cooling pipe comprises an inlet end and an outlet end, the cooling liquid of the upper cooling pipe flows along the upper cooling pipe from the inlet end to the outlet end; and the inlet end and the outlet end of the upper cooling pipe are connected to an upper pump such that the cooling liquid cyclically flows between the upper cooling pipe and the upper pump.

An objective of the present invention is to provide a vapor deposition mask plate for a display panel, comprising:

a plate member;

a frame disposed around a periphery of the plate member; and

a mask cooling pipe disposed in the frame, wherein the cooling liquid is further disposed in the mask cooling pipe and is configured to cool the vapor deposition mask plate.

In an embodiment of the present invention, the mask cooling pipe comprises an inlet end and an outlet end, the cooling liquid in the mask cooling pipe flows along the mask cooling pipe from the inlet end to the outlet end.

In an embodiment of the present invention, the inlet end and the outlet end of the mask cooling pipe are connected to a circulating pump such that the cooling liquid flows cyclically between the mask cooling pipe and the circulating pump.

In an embodiment of the present invention, two connection pipes are disposed on the circulating pump and are connected to the inlet end and the outlet end of the mask cooling pipe respectively, and a distal end of each of the connection pipes is shrunk to form an engaging section engaged with and inserted into the inlet end or the outlet end.

In an embodiment of the present invention, the vapor deposition mask plate comprises a plate member and a frame disposed around a periphery of the plate member; and the mask cooling pipe is disposed in the frame.

In an embodiment of the present invention, the mask cooling pipe is arranged along the frame to form at least one loop surrounding the plate member.

In an embodiment of the present invention, the plate member has a plurality of vapor deposition holes penetrating the plate member.

In an embodiment of the present invention, the frame of the vapor deposition mask plate is rectangular and comprises four sides, the inlet end and the outlet end of the mask cooling pipe is located on one of the sides of the frame.

### Advantages

Compared to the prior art, the display panel vapor deposition mask assembly cooling system and the vapor deposition mask plate of the present invention mainly disposes the mask cooling pipe in the vapor deposition mask plate and injects the cooling liquid in the mask cooling pipe to directly dissipate heat of the vapor deposition mask plate cyclically such that a cooling efficiency to the vapor deposition mask plate and the glass substrate above the vapor deposition mask plate is improved. Therefore, the issue of color mixture due to heat expansion of the mask plate and the glass substrate during the vapor deposition process is decreased. Therefore, a yield rate of the organic light emitting diode (OLED) display panel products can be drastically improved.

To make the above descriptions of the present invention clearer and more easily understandable, embodiments with accompanying drawings are described as follows.

### DESCRIPTION OF DRAWINGS

FIG. 1 is a schematic front view of devices of a conventional vapor deposition process.

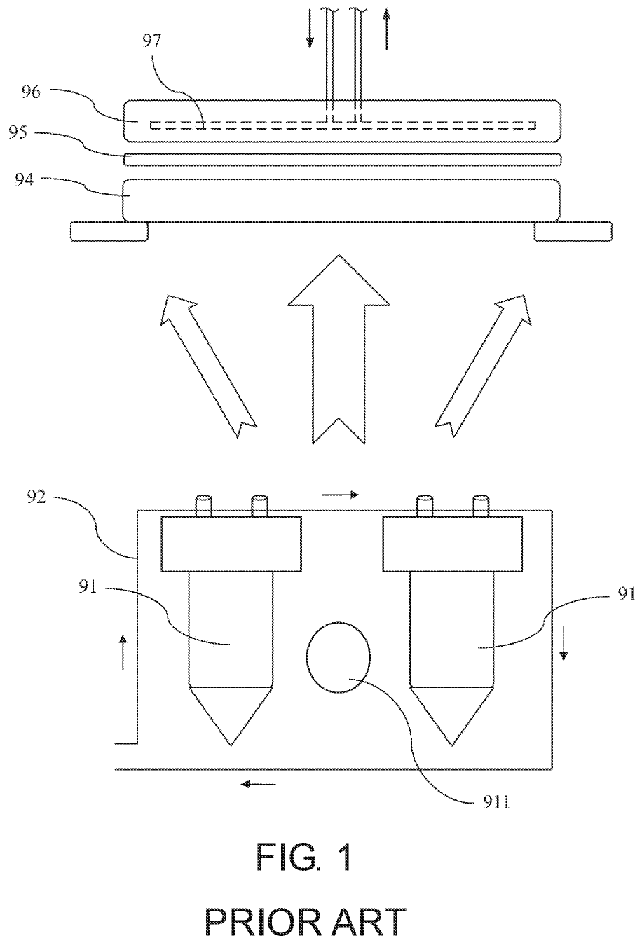

FIG. 2 is a schematic front view of a display panel vapor deposition mask assembly cooling system of the present invention.

FIG. 3 is a schematic top view of the vapor deposition mask plate of the present invention.

FIG. 4 is a schematic enlarged front view of an inlet end and an outlet end of the vapor deposition mask plate of the present invention.

FIG. 5 is a schematic enlarged cross sectional side view of the inlet end of the vapor deposition mask plate of the present invention.

### DETAILED DESCRIPTION OF PREFERRED EMBODIMENTS

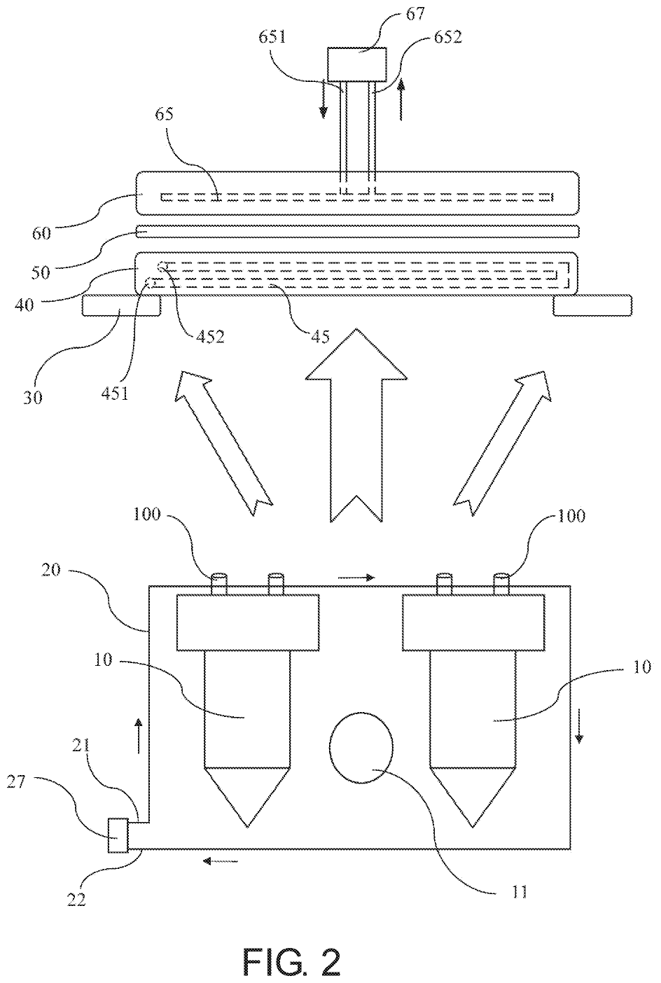

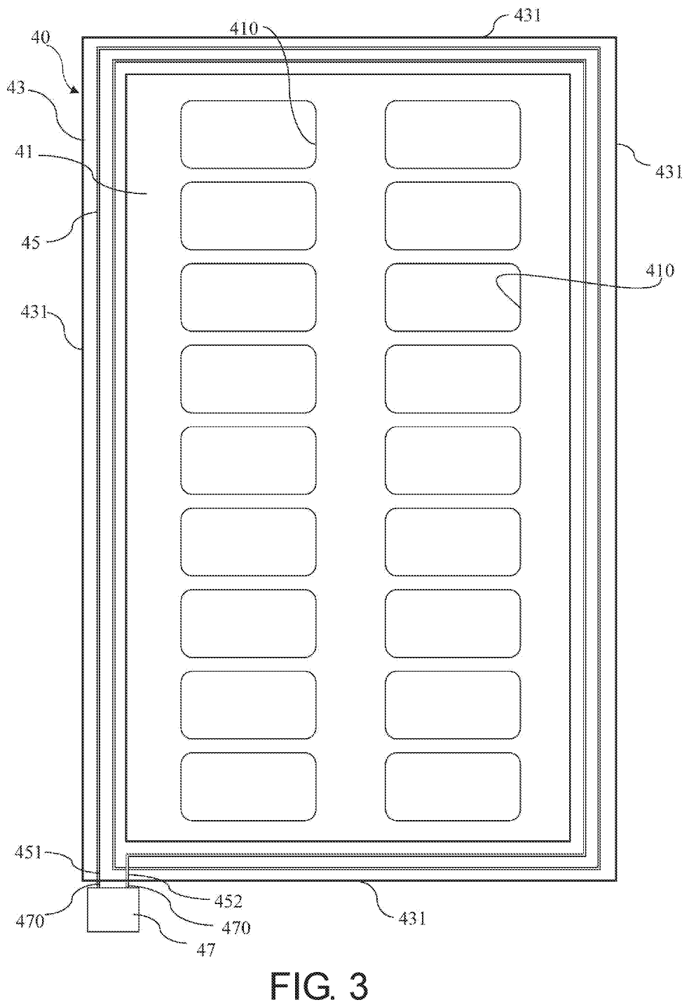

With reference to FIGS. 2 and 3, a display panel vapor deposition mask assembly cooling system of the present invention is configured to dissipate heat from a vapor deposition mask assembly. The vapor deposition mask assembly comprises a vapor deposition mask plate 40, a glass substrate 50 disposed above the vapor deposition mask plate 40, and a magnetic plate 60 disposed above the glass substrate 50.

The display panel vapor deposition mask assembly cooling system of the present invention includes a lower cooling pipe 20, a mask cooling pipe 40, and an upper cooling pipe 65.

The lower cooling pipe 20 is configured to be disposed around a periphery of the crucible 10. Cooling liquid is disposed in the lower cooling pipe 20 to suppress heat generated by the crucible 10. The cooling liquid can be water, alcohol, or any evaporable liquid. Furthermore, a nozzle 100 is disposed on a top of the crucible 10. The crucible 10 can be filled with an organic light emitting diode (OLED) material. In an embodiment of the present invention, the lower cooling pipe 20 includes an inlet end 21 and an outlet end 22, the cooling liquid in the lower cooling pipe 20 flows along the lower cooling pipe 20 from the inlet end 21 to the outlet end 22. Furthermore, the inlet end 21 and the outlet end 22 of the lower cooling pipe 20 are connected to a lower pump 27 such that the cooling liquid cyclically flows between the lower cooling pipe 20 and the lower pump 27. A heatsink or other heat exchanger can be disposed on the lower pump 27 for assisting heat dissipation of the cooling liquid.

The mask cooling pipe 45 is disposed in the vapor deposition mask plate 40. Cooling liquid is disposed in the mask cooling pipe 45 to cool the vapor deposition mask plate 40. The cooling liquid can be water, alcohol, or any evaporable liquid. The mask cooling pipe 45 can be made of stainless steel. The vapor deposition mask plate 40 can be mounted through a bracket 30 above the crucible 10. The vapor deposition mask plate 40 includes a plate member 41 and a frame 43. A plurality of vapor deposition holes 410 are defined through the plate member 41 such that the sublimated OLED material is deposited on the glass substrate 50 through the vapor deposition holes 410. The frame 43 is disposed around a periphery of the plate member 41. The mask cooling pipe 45 is disposed in the frame 43. Furthermore, the frame 43 of the vapor deposition mask plate 40 can be rectangular and includes four sides 431, and a width of the frame 43 can be 50 mm. In an embodiment of the present invention, the mask cooling pipe 45 is arranged along the frame 43 to form at least one loop surrounding the plate member 41. Furthermore, the mask cooling pipe 45 an be a component installed onto the vapor deposition mask plate 40, or alternatively can be an integral part formed integrally in the vapor deposition mask plate 40 by forging or cutting processes for the vapor deposition mask plate 40.

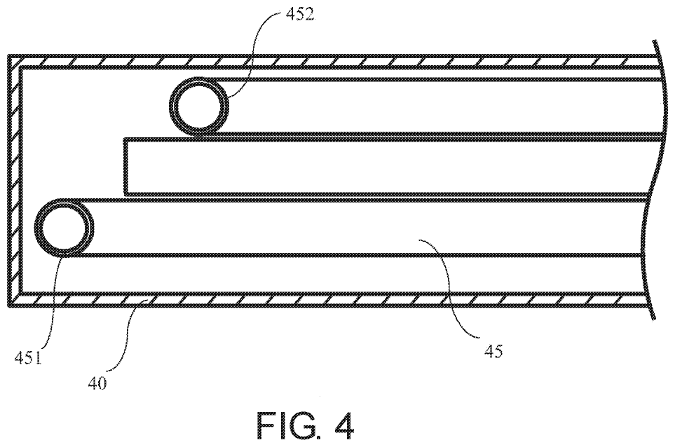

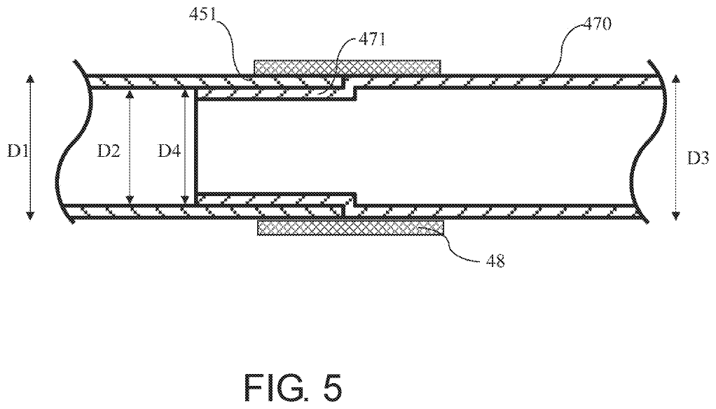

With reference to FIGS. 4 and 5, the mask cooling pipe 45 includes an inlet end 451 and an outlet end 452. The cooling liquid in the mask cooling pipe 45 flows from the inlet end 451 to the outlet end 452 along the mask cooling pipe 45. The inlet end 451 and the outlet end 452 of the mask cooling pipe 45 can be located on one of the sides 431 of the frame 43. The inlet end 451 and the outlet end 452 of the mask cooling pipe 45 are connected to a circulating pump 47 such that the cooling liquid cyclically flows between the mask cooling pipe 45 and the circulating pump 47. Two connection pipes 470 are disposed on the circulating pump 47 and are connected to the inlet end 451 and the outlet end 452 of the mask cooling pipe 45 respectively. A distal end of each of the connection pipes 470 is shrunk to form an engaging section 471 engaged with and inserted into the inlet end 451 or the outlet end 452. Furthermore, a rubber sealing sleeve 48 can disposed around an engaging portion between each of the connection pipes 470 and a corresponding one of the inlet end 451 or the outlet end 452 to provide hermetical ability to the portion. Furthermore, a heatsink or other heat exchanger can be disposed on the circulating pump 47 for assisting heat dissipation of the cooling liquid. In an embodiment of the present invention, an outer diameter of the inlet end 451 D1 of the mask cooling pipe 45 is 10 mm, an inner diameter D2 thereof is 5 mm, an outer diameter D3 of the outlet end 452 is 10 mm, an inner diameter D4 thereof is 5 mm. An outer diameter of the engaging section 471 of each of the connection pipes 470 is 5 mm.

The glass substrate 50 is disposed above the vapor deposition mask plate 40.

The upper cooling pipe 65 is disposed in the magnetic plate 60. Cooling liquid is disposed in the upper cooling pipe 65 to cool the magnetic plate 60. The cooling liquid can be water, alcohol, or any evaporable liquid. In an embodiment of the present invention, the upper cooling pipe 65 includes an inlet end 651 and an outlet end 652, the cooling liquid in the upper cooling pipe 65 flows from the inlet end 651 to the outlet end 652 along the upper cooling pipe 65. Furthermore, the inlet end 651 and the outlet end 652 of the upper cooling pipe 65 are connected to an upper pump 67 such that the cooling liquid cyclically flows between the upper cooling pipe 65 and the upper pump 67. A heatsink or other heat exchanger can be disposed on the upper pump 67 for assisting heat dissipation of the cooling liquid. The magnetic plate 60 magnetically attracts the vapor deposition mask plate 40 by a magnetic force such that the glass substrate 50 is clamped and held securely between the vapor deposition mask plate 40 and the magnetic plate 60.

When the vapor deposition process is implemented, an evaporation source (or called heating source) 11 heats the crucible 10 loaded with OLED material such that the heated and sublimated OLED material is sprayed through the nozzle 100 on the top of the crucible 10 and is deposited on the glass substrate 50 above. Because sublimating temperatures of most of the OLED material is over 400° C., waste heat of the evaporation source 11 spreads onto the vapor deposition mask plate 40 and the glass substrate 50 in form of heat radiation, which causes temperature increase of the vapor deposition mask plate 40. Because the mask cooling pipe 45 and the cyclically flowing cooling liquid in the vapor deposition mask plate 40 instantly dissipate heat of the vapor deposition mask plate 4, the temperature of the vapor deposition mask plate 40 can be effectively controlled within a reasonable temperature range. Furthermore, because the vapor deposition mask plate 40 under the glass substrate 50 dissipates most heat of the evaporation source 11 in advance, the glass substrate 50 located above the vapor deposition mask plate 40 absorbs fewer heat such that an amount of the increased temperature of the glass substrate 50 is reduced to prevent the issue of color mixture during the OLED material vapor deposition process.

Compared to the prior art, the display panel vapor deposition mask assembly 40 cooling system and the vapor deposition mask plate 40 of the present invention mainly dispose the mask cooling pipe 45 in the vapor deposition mask plate 40 and injects the cooling liquid into the mask cooling pipe 45 to directly dissipate heat of the vapor deposition mask plate 40 cyclically such that a cooling efficiency to the vapor deposition mask plate 40 and the glass substrate 50 above the vapor deposition mask plate 40 is improved. Therefore, the issue of color mixture due to heat expansion of the mask plate and the glass substrate 50 during the vapor deposition process is decreased. Therefore, a product yield of the organic light emitting diode (OLED) display panel products can be greatly improved.

What is claimed is:

1. A display panel vapor deposition mask assembly cooling system, configured to dissipate heat from a vapor deposition mask assembly, the vapor deposition mask assembly comprising a vapor deposition mask plate, a glass substrate disposed above the vapor deposition mask plate, and a magnetic plate disposed above the glass substrate; the display panel vapor deposition mask assembly cooling system comprising:
a mask cooling pipe, disposed in the vapor deposition mask plate, wherein cooling liquid is disposed in the mask cooling pipe and configured to cool the vapor deposition mask plate.

2. The display panel vapor deposition mask assembly cooling system as claimed in claim 1 further comprising:
a lower cooling pipe, wherein the cooling liquid is further disposed in the lower cooling pipe.

3. The display panel vapor deposition mask assembly cooling system as claimed in claim 2 further comprising:
an upper cooling pipe, disposed in the magnetic plate, wherein the cooling liquid is further disposed in the upper cooling pipe and is configured to cool the magnetic plate.

4. The display panel vapor deposition mask assembly cooling system as claimed in claim 3, wherein the mask cooling pipe comprises an inlet end and an outlet end, the cooling liquid in the mask cooling pipe flows along the mask cooling pipe from the inlet end to the outlet end.

5. The display panel vapor deposition mask assembly cooling system as claimed in claim 4, wherein the inlet end and the outlet end of the mask cooling pipe are connected to a circulating pump such that the cooling liquid flows cyclically between the mask cooling pipe and the circulating pump.

6. The display panel vapor deposition mask assembly cooling system as claimed in claim 5, wherein two connection pipes are disposed on the circulating pump and are connected to the inlet end and the outlet end of the mask cooling pipe respectively, and a distal end of each of the connection pipes is shrunk to form an engaging section engaged with and inserted into the inlet end or the outlet end.

7. The display panel vapor deposition mask assembly cooling system as claimed in claim 3, wherein the vapor deposition mask plate comprises a plate member and a frame disposed around a periphery of the plate member; and the mask cooling pipe is disposed in the frame.

8. The display panel vapor deposition mask assembly cooling system as claimed in claim 7, wherein the mask cooling pipe is arranged along the frame to form at least one loop surrounding the plate member.

9. The display panel vapor deposition mask assembly cooling system as claimed in claim 7, wherein the plate member has a plurality of vapor deposition holes penetrating the plate member.

10. The display panel vapor deposition mask assembly cooling system as claimed in claim 7, wherein the frame of the vapor deposition mask plate is rectangular and comprises four sides, the inlet end and the outlet end of the mask cooling pipe are located on one of the sides of the frame.

11. The display panel vapor deposition mask assembly cooling system as claimed in claim 3, wherein the lower cooling pipe comprises an inlet end and an outlet end, the cooling liquid in the lower cooling pipe flows along the lower cooling pipe from the inlet end to the outlet end; the inlet end and the outlet end of the lower cooling pipe are connected to a lower pump such that the cooling liquid cyclically flows between the lower cooling pipe and the lower pump.

12. The display panel vapor deposition mask assembly cooling system as claimed in claim 3, wherein the upper cooling pipe comprises an inlet end and an outlet end, the cooling liquid of the upper cooling pipe flows along the upper cooling pipe from the inlet end to the outlet end; and the inlet end and the outlet end of the upper cooling pipe are connected to an upper pump such that the cooling liquid cyclically flows between the upper cooling pipe and the upper pump.

13. A vapor deposition mask plate for a display panel, comprising:
a plate member;
a frame disposed around a periphery of the plate member; and
a mask cooling pipe disposed in the frame, wherein the cooling liquid is further disposed in the mask cooling pipe and is configured to cool the vapor deposition mask plate.

14. The vapor deposition mask plate for the display panel as claimed in claim 13, wherein the mask cooling pipe comprises an inlet end and an outlet end, the cooling liquid in the mask cooling pipe flows along the mask cooling pipe from the inlet end to the outlet end.

15. The vapor deposition mask plate for the display panel as claimed in claim 14, wherein the inlet end and the outlet end of the mask cooling pipe are connected to a circulating pump such that the cooling liquid flows cyclically between the mask cooling pipe and the circulating pump.

16. The vapor deposition mask plate for the display panel as claimed in claim 15, wherein two connection pipes are disposed on the circulating pump and are connected to the inlet end and the outlet end of the mask cooling pipe respectively, and a distal end of each of the connection pipes is shrunk to form an engaging section engaged with and inserted into the inlet end or the outlet end.

17. The vapor deposition mask plate for the display panel as claimed in claim 13, wherein the vapor deposition mask plate comprises a plate member and a frame disposed around a periphery of the plate member; and the mask cooling pipe is disposed in the frame.

18. The vapor deposition mask plate for the display panel as claimed in claim 13, wherein the mask cooling pipe is arranged along the frame to form at least one loop surrounding the plate member.

19. The vapor deposition mask plate for the display panel as claimed in claim 13, wherein the plate member has a plurality of vapor deposition holes penetrating the plate member.

20. The vapor deposition mask plate for the display panel as claimed in claim 13, wherein the frame of the vapor deposition mask plate is rectangular and comprises four sides, the inlet end and the outlet end of the mask cooling pipe is located on one of the sides of the frame.
